(19) United States
(12) Patent Application Publication
(10) Pub. No.: US 2026/0247899 A1
(43) Pub. Date: Aug. 20, 2026

(54) SUBSTRATE PROCESSING APPARATUS, SUBSTRATE PROCESSING METHOD, AND COMPUTER-READABLE RECORDING MEDIUM

(71) Applicant: Tokyo Electron Limited, Tokyo (JP)

(72) Inventor: Kyosei GOTO, Koshi City, Kumamoto (JP)

(73) Assignee: Tokyo Electron Limited, Tokyo (JP)

(21) Appl. No.: 18/872,281

(22) PCT Filed: May 25, 2023
(86) PCT No.: PCT/JP2023/019485

§ 371 Date: Dec. 6, 2024

(30) Foreign Application Priority Data
Jun. 8, 2022 (JP) 2022-093112

(51) Int. Cl. H10P 72/00; H10P 72/76

(52) U.S. Cl. CPC H10P 72/0414; H10P 72/0432; H10P 72/0602; H10P 72/0616; H10P 72/7618

(57) ABSTRACT

A substrate processing apparatus includes a rotating/holding device for holding and rotating a substrate, a processing liquid supply for supplying a processing liquid to a peripheral portion of the substrate, a heating device for heating a region including a central portion of the substrate, a peripheral heating device for heating the peripheral portion of the substrate, and a controller for controlling the rotating/holding device to rotate the substrate, the processing liquid supply to supply the processing liquid to the peripheral portion of the substrate, and the heating device and the peripheral heating device to heat the region including the central portion of the substrate and the peripheral portion of the substrate, respectively, such that a temperature difference between the region including the central portion of the substrate and the peripheral portion of the substrate falls within a preset range.

### TECHNICAL FIELD

The various aspects and embodiments described herein pertain generally to a substrate processing apparatus, a substrate processing method, and a computer-readable recording medium.

### BACKGROUND

Patent Document 1 discloses a substrate processing apparatus equipped with a holder configured to hold a substrate rotatably, a supply configured to supply a processing liquid to the substrate held by the holder, and a heater configured to heat the substrate by supplying a heated nitrogen gas to a bottom surface of the substrate.

### PRIOR ART DOCUMENT

Patent Document 1: Japanese Patent Laid-open Publication No. 2019-134000

### DISCLOSURE OF THE INVENTION

### Problems to be Solved by the Invention

Exemplary embodiments provide a substrate processing apparatus, a substrate processing method, and a computer-readable recording medium enabling a highly precise processing of a peripheral portion of a substrate.

### Means for Solving the Problems

In an exemplary embodiment, a substrate processing apparatus includes a rotating/holding device configured to hold and rotate a substrate; a processing liquid supply configured to supply a processing liquid to a peripheral portion of the substrate; a heating device configured to heat a region including a central portion of the substrate; a peripheral heating device configured to heat the peripheral portion of the substrate; and a controller. The controller is configured to perform: rotating the substrate by controlling the rotating/holding device; supplying the processing liquid to the peripheral portion of the substrate being rotated by controlling the processing liquid supply; and heating, by controlling the heating device and the peripheral heating device, at least while the processing liquid is being supplied to the peripheral portion of the substrate, the region including the central portion of the substrate and the peripheral portion of the substrate, respectively, such that a temperature difference between the region including the central portion of the substrate and the peripheral portion of the substrate falls within a preset range.

### Effect of the Invention

According to the exemplary embodiment, it is possible to provide the substrate processing apparatus, the substrate processing method, and the computer-readable recording medium enabling the highly precise processing of the peripheral portion of the substrate.

### BRIEF DESCRIPTION OF THE DRAWINGS

FIG. 1 is a plan view schematically illustrating an example of a substrate processing system.

FIG. 2 is a side view schematically illustrating an example of a liquid processing module.

FIG. 3 is a schematic side view mainly illustrating a heating device of FIG. 2.

FIG. 4 is a top view of the liquid processing module of FIG. 3.

FIG. 5 is a block diagram illustrating an example of main parts of the substrate processing system.

FIG. 6 is a schematic diagram illustrating an example of a hardware configuration of a controller.

FIG. 7 is a flowchart illustrating an example of a substrate processing sequence.

FIG. 8A to FIG. 8C are cross sectional views illustrating an example of the substrate processing sequence.

FIG. 9 is a diagram illustrating changes over time in flow rates of fluids, a temperature of the heating device, and a temperature of a peripheral heating device.

FIG. 10 is a diagram showing a change in temperature over time at different positions on a substrate (at a position of 74 mm and a position of 149 mm from the center of the substrate) having a diameter of 300 mm.

FIG. 11 is a top view of another example of the liquid processing module.

### DETAILED DESCRIPTION

In the following description, same parts or parts having same functions will be assigned same reference numerals, and redundant descriptions thereof will be omitted. Further, in the present specification, when referring to the top, bottom, right, and left of a drawing, it is based on the direction of a symbol in the drawing.

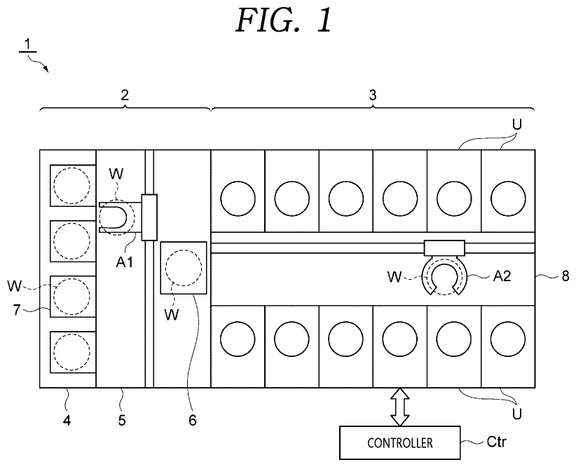

First, referring to FIG. 1, a substrate processing system 1 (substrate processing apparatus) configured to process a substrate W will be explained. The substrate processing system 1 includes a carry-in/out station 2, a processing station 3, and a controller Ctr (control device). The carry-in/out station 2 and the processing station 3 may be arranged in a row in a horizontal direction, for example.

The substrate W may be of a circular plate shape, or may be of a plate shape other than a circle, such as a polygon. The substrate W may have a groove portion which is partially cut out. The groove portion may be, by way of example, a notch (a groove of a U-shape, a V-shape, etc.) or a linear portion (so-called orientation flat) extending linearly. The substrate W may be, by way of non-limiting example, a semiconductor substrate (silicon wafer), a glass substrate, a mask substrate, a flat panel display (FPD) substrate, or any of various other kinds of substrates. The substrate W may have a diameter ranging from, e.g., about 200 mm to about 450 mm.

The substrate W includes a central region Wa and a peripheral region Wb. The central region Wa is a region that includes the center of the substrate W and does not reach the peripheral region Wb. The peripheral region Wb is a region that includes an outer periphery of the substrate W and has a preset width in a radial direction of the substrate W. The diameter of the central region Wa may be in the range of about 0 mm to about 100 mm, and the width of the peripheral region Wb in the radial direction may be in the range of about 100 mm to about 150 mm.

The carry-in/out station 2 includes a placement section 4, a carry-in/out section 5, and a shelf section 6. The placement section 4 includes a plurality of placement tables (not shown) arranged in a width direction (up-and-down direction in FIG. 1). Each placement table is configured to place a carrier 7 thereon. The carrier 7 is configured to accommodate at least one substrate W in a sealed state. The carrier 7 includes an opening/closing door (not shown) through which the substrate W is carried in or out.

The carry-in/out section 5 is disposed adjacent to the placement section 4 in a direction in which the carry-in/out station 2 and the processing station 3 are arranged (left-and-right direction in FIG. 1). The carry-in/out section 5 includes an opening/closing door (not shown) for the placement section 4. When the opening/closing door of the carrier 7 and the opening/closing door of the carry-in/out section 5 are both opened in the state that the carrier 7 is placed on the placement section 4, the inside of the carry-in/out section 5 and the inside of the carrier 7 communicate with each other.

The carry-in/out section 5 has a transfer arm A1 and the shelf section 6 therein. The transfer arm A1 is configured to be movable horizontally in a width direction of the carry-in/out section 5, movable up and down in a vertical direction, and pivotable around a vertical axis. The transfer arm A1 serves to take out the substrate W from the carrier 7 and hand it over to the shelf section 6, and also serves to receive the substrate W from the shelf section 6 and return it back into the carrier 7. The shelf section 6 is located in the vicinity of the processing station 3, and is configured to accommodate the substrate W therein.

The processing station 3 includes a transfer section 8 and a plurality of liquid processing modules U. For example, the transfer section 8 extends horizontally in the direction (left-and-right direction in FIG. 1) in which the carry-in/out station 2 and the processing station 3 are arranged. The transfer section 8 incorporates a transfer arm A2 (transfer device) therein. The transfer arm A2 is configured to be movable horizontally in a lengthwise direction of the transfer section 8, movable up and down in a vertical direction, and pivotable around a vertical axis. The transfer arm A2 serves to take out the substrate W or a test substrate J from the shelf section 6 and hand it over to the liquid processing module U, and also serves to receive the substrate W from the liquid processing module U and return it back into the shelf section 6.

The plurality of liquid processing modules U are arranged in a row along the lengthwise direction (left-and-right direction in FIG. 1) of the transfer section 8 at both sides of the transfer section 8. Each liquid processing module U is configured to perform a predetermined processing (for example, an etching processing, a cleaning processing, etc.) on the substrate W. Details of the liquid processing module U will be described later.

The controller Ctr is configured to control the substrate processing system 1 partially or in overall. Details of the controller Ctr will be discussed later.

### Details of Liquid Processing Module

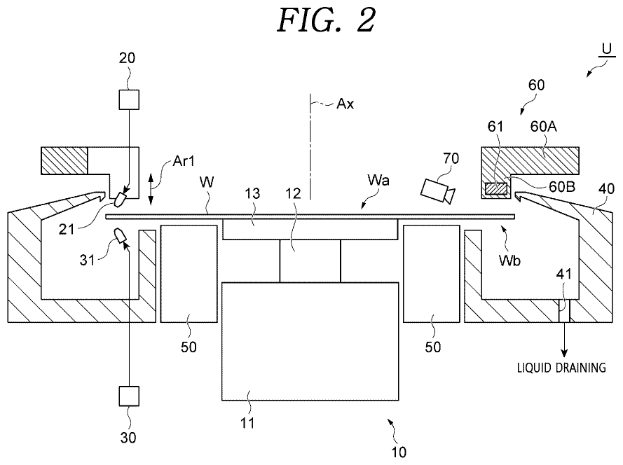

Now, referring to FIG. 2 to FIG. 4, the liquid processing module U will be described in detail. The liquid processing module U (substrate processing apparatus) includes, as illustrated in FIG. 2, a rotating/holding device 10, processing liquid supplies 20 and 30, a cup member 40, a heating device 50, a cover 60, and a detector 70 (detecting device).

The rotating/holding device 10 includes a driver 11, a shaft 12, and a holder 13. The driver 11 is operated based on an operation signal from the controller Ctr, and is configured to rotate the shaft 12. The driver 11 may be a power source such as, but not limited to, an electric motor.

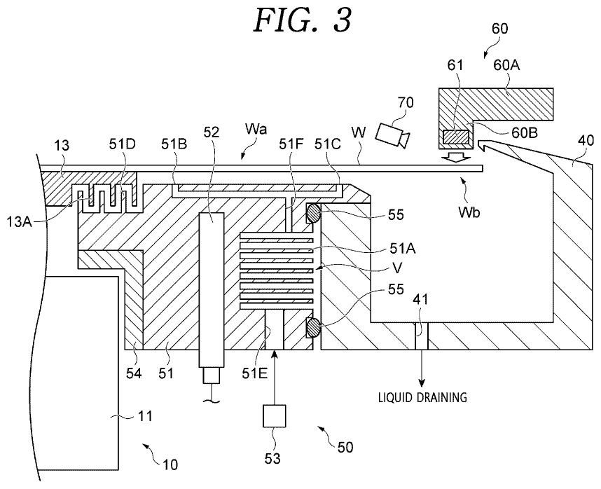

The holder 13 is provided at a leading end of the shaft 12. The holder 13 is configured to attract and hold a rear surface of the substrate W by, for example, attraction. That is, the rotating/holding device 10 may be configured to rotate the substrate W around a rotation center axis Ax (see FIG. 2) perpendicular to a front surface of the substrate W, while holding the substrate W in a substantially horizontal posture. A plurality of labyrinth members 13A is provided in an outer portion of a bottom surface of the holder 13 in a radial direction, as illustrated in FIG. 3. The plurality of labyrinth members 13A have a substantially cylindrical shape, and are arranged in a substantially concentric manner at a certain distance therebetween.

The processing liquid supply 20 includes a liquid source, a valve, a pipeline, etc., that are not shown. The processing liquid supply 20 is operated based on an operation signal from the controller Ctr, and is configured to supply a processing liquid stored in the liquid source to a top surface of the substrate W from a nozzle 21. The processing liquid stored in the liquid source may be, by way of non-limiting example, an acidic chemical liquid, an alkaline chemical liquid, an organic chemical liquid, or a rinse liquid. The acidic chemical liquid may include, for example, a SC-2 liquid (a mixture of hydrochloric acid, hydrogen peroxide, and pure water), SPM (a mixture of sulfuric acid and a hydrogen peroxide solution), a HF liquid (hydrofluoric acid), a DHF liquid (dilute hydrofluoric acid), a HNO₃+HF liquid (a mixture of nitric acid and hydrofluoric acid), or the like. The alkaline chemical liquid may include, for example, a SC-1 liquid (a mixture of ammonia, hydrogen peroxide, and pure water), a hydrogen peroxide solution, or the like. The organic solvent may include, for example, IPA (isopropyl alcohol). The rinse liquid may include, for example, pure water (DIW: deionized water), ozone water, carbonated water (CO2 water), ammonia water, or the like.

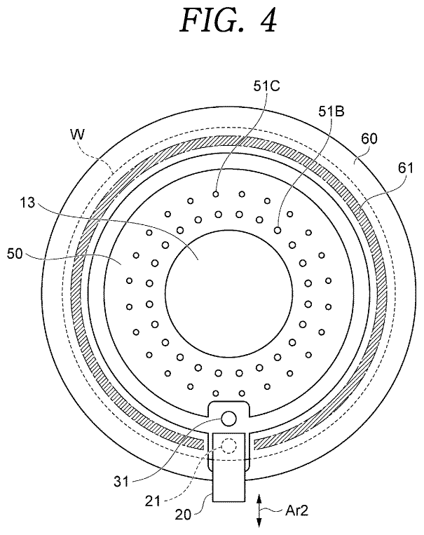

The nozzle 21 is disposed above the substrate W held by the rotating/holding device 10, as illustrated in FIG. 2. A discharge opening of the nozzle 21 may be directed toward the top surface of the substrate W and may also be directed toward the outer periphery of the substrate W. Therefore, the processing liquid discharged from the nozzle 21 is supplied to the peripheral region Wb of the top surface of the substrate W. The nozzle 21 may be configured to be moved horizontally or up and down above the substrate W by a non-illustrated driving source (see an arrow Ar1 in FIG. 2 and an arrow Ar2 in FIG. 4).

The processing liquid supply 30 includes a liquid source, a valve, a pipeline, etc., that are not shown. The processing liquid supply 30 is operated based on an operation signal from the controller Ctr, and is configured to supply a processing liquid stored in the liquid source from a nozzle 31 to a bottom surface of the substrate W. The processing liquid stored in the liquid source may be the same as the processing liquid stored in the liquid source of the processing liquid supply 20.

The nozzle 31 is disposed below the substrate W held by the rotating/holding device 10. A discharge opening of the nozzle 31 may be directed toward the bottom surface of the substrate W and may also be directed toward the outer periphery of the substrate W. Therefore, the processing liquid discharged from the nozzle 31 is supplied to the peripheral region Wb of the bottom surface of the substrate W.

The cup member 40 is configured to surround the rotating/holding device 10 and the heating device 50. The cup member 40 is configured to collect the processing liquid scattered from the outer periphery of the substrate W when the processing liquid is supplied to the substrate W held and being rotated by the rotating/holding device 10. A drain port 41 is provided at a bottom portion of the cup member 40. The drain port 41 is configured to drain the processing liquid collected by the cup member 40 to the outside of the liquid processing module U.

The heating device 50 may be positioned below the substrate W held by the rotating/holding device 10, as illustrated in FIG. 3. The heating device 50 includes a main body 51, a heat source 52, a fluid supply 53, and a heat insulating member 54. The main body 51 is configured to surround the rotating/holding device 10, and is positioned between the rotating/holding device 10 and the cup member 40. Specifically, an outer surface of the main body 51 is in contact with an inner surface of the cup member 40 with a plurality of seal members 55 (for example, O-rings) therebetween. Therefore, a space V surrounded by the outer surface of the main body 51, the inner surface of the cup member 40, and the plurality of seal members 55 is maintained air-tight.

A plurality of fins 51A is provided in the space V of the main body 51. The plurality of fins 51A are arranged in a vertical direction with a preset distance therebetween within the space V. Each of the plurality of fins 51A may be, for example, a plate-shaped body extending along a circumferential direction of the main body 51.

A plurality of discharge openings 51B and a multiplicity of discharge openings 51C are provided in a top surface of the main body 51, as illustrated in FIG. 3 and FIG. 4, for example. The plurality of discharge openings 51B are arranged in a circular shape along the circumferential direction of the main body 51. The plurality of discharge openings 51B are positioned so as to face an area near the center of the substrate W in the central region Wa when the substrate W is held by the rotating/holding device 10. The multiplicity of discharge openings 51C are arranged in a circular shape along the circumferential direction of the main body 51. The multiplicity of discharge openings 51C are provided radially outside the plurality of discharge openings 51B. The multiplicity of discharge openings 51C are positioned so as to face an area near the outer periphery of the substrate W in the central region Wa when the substrate W is held by the rotating/holding device 10.

As illustrated in FIG. 3, a plurality of labyrinth members 51D is provided at a radially inner portion of the top surface of the main body 51. The plurality of labyrinth members 51D have a substantially cylindrical shape, and are arranged in a substantially concentric shape with a certain distance therebetween. The plurality of labyrinth members 51D are arranged alternately with respect to the plurality of labyrinth members 13A. That is, the plurality of labyrinth members 51D and the plurality of labyrinth members 13A are arranged alternately in the radial direction. A labyrinth structure formed by these labyrinth members 13A and 51D suppresses unheated air from being introduced between the substrate W and the main body 51. Therefore, heating efficiency for the substrate W by the heating device 50 may be improved.

The main body 51 is provided with a flow path 51E that connects the bottom surface of the main body 51 and the space V in a fluidic manner. The flow path 51E extends vertically from the bottom surface of the main body 51 toward the space V. A flow path 51F of the main body 51 connects the plurality of discharge openings 51B and the multiplicity of discharge openings 51C to the space V in a fluidic manner. The flow path 51F extends upwards from the space V and then branches out to extend toward the plurality of discharge openings 51B and the multiplicity of discharge openings 51C, respectively.

The heat source 52 is embedded in the main body 51 so as to be located near the plurality of fins 51A. The heat source 52 is operated based on an operation signal from the controller Ctr, and is configured to heat the plurality of fins 51A. The heat source 52 may be a resistance heater (for example, a sheath heater).

The fluid supply 53 includes a liquid source, a valve, a pipeline, etc., that are not shown. The fluid supply 53 is operated based on an operation signal from the controller Ctr, and is configured to supply a fluid stored in the fluid source to the flow path 51E. The fluid may be an inert gas (for example, a nitrogen gas). Once the fluid is supplied into the flow path 51E by the fluid supply 53, the fluid reaches the space V, and heat transfer occurs between the fluid and the plurality of fins 51A. The fluid thus heated flows through the flow path 51F to be discharged toward the bottom surface (central region Wa) of the substrate W from the discharge openings 51B and 51C. As a result, the center region Wa of the substrate W is heated from the bottom surface side of the substrate W.

The heat insulating member 54 is disposed in a region of the inner surface of the main body 51 facing the driver 11. The heat insulating member 54 is configured to suppress the heat of the main body 51 heated by the heat source 52 from being transferred to the rotating/holding device 10.

The cover 60 is disposed so as to be located above the cup member 40 and above the substrate W held by the rotating/holding device 10. As illustrated in FIG. 4, the cover 60 has a ring shape (for example, a circular ring shape) or an arc shape (for example, a circular arc shape) as a whole. The cover 60 has a function of rectifying a downflow formed by a blower (not shown) disposed near the ceiling of the liquid processing module U and flowing the downflow from the central region Wa of the substrate W toward the peripheral region Wb.

The cover 60 includes a base member 60A and a protruding member 60B, as illustrated in FIG. 2 and FIG. 3. The base member 60A has an annular plate shape. The protruding member 60B protrudes downwards from an inner peripheral portion of the base member 60A, and has a substantially cylindrical shape. A lower portion of the protruding member 60B faces the peripheral region Wb of the substrate W held by the rotating/holding device 10.

Disposed inside the protruding member 60B is a peripheral heating device 61. The peripheral heating device 61 is operated based on an operation signal from the controller Ctr, and is configured to heat the peripheral region Wb of the substrate W. The peripheral heating device 61 may be disposed in the substantially entire region of the protruding member 60B, as illustrated in FIG. 4. The peripheral heating device 61 may be configured to heat the peripheral region Wb of the substrate W by, for example, induction heating. Alternatively, the peripheral heating device 61 may be configured to heat the peripheral region Wb of the substrate W by, for example, discharging a heated fluid (for example, a nitrogen gas) from a bottom surface of the protruding member 60B. Still alternatively, the peripheral heating device 61 may be configured to heat the peripheral region Wb of the substrate W by, for example, radiant heat.

The detector 70 is disposed above the peripheral region Wb of the substrate W, as shown in FIG. 2 and FIG. 3. The detector 70 is operated based on an operation signal from the controller Ctr, and is configured to detect a bending amount of the peripheral region Wb of the substrate W. The detector 70 is configured to output the detected bending amount to the controller Ctr. The detector 70 may be an imaging device such as a CCD camera or a COMS camera, or a measurement device such as a laser displacement meter. The installation location of the detector 70 is not particularly limited as long as it is located within the liquid processing module U.

### Details of Controller

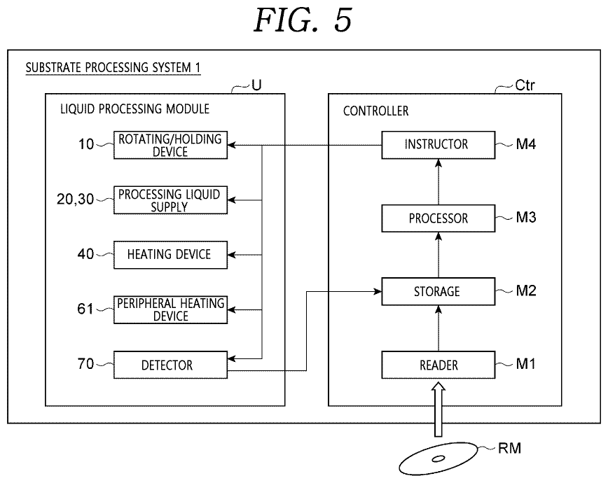

As shown in FIG. 5, the controller Ctr has, as functional modules, a reader M1, a storage M2, a processor M3, and an instructor M4. These functional modules merely correspond to the functions of the controller Ctr for the sake of conveniences, and do not necessarily mean that the hardware constituting the controller Ctr is divided into these modules. Each functional module is not limited to being implemented by execution of a program, but may be implemented by a dedicated electric circuit (e.g., a logic circuit) or an integrated circuit (ASIC: Application Specific Integrated Circuit) thereof.

The reader M1 is configured to read a program from a computer-readable recording medium RM. The recording medium RM stores a program for operating the individual components of the substrate processing system 1 including the liquid processing module U. The recording medium RM may be, by way of non-limiting example, a semiconductor memory, an optical recording disk, a magnetic recording disk, or a magneto-optical recording disk. In addition, in the following description, the individual components of the substrate processing system 1 may include the rotating/holding device 10, the processing liquid supplies 20 and 30, the heating device 50, a peripheral heating device 61, and the detector 70.

The storage M2 is configured to store various data. The storage M2 may store, for example, the program read from the recording medium RM in the reader M1, setting data inputted from an operator through an external input device (not shown), and so forth. The storage M2 may store data of an image obtained by the detector 70. The storage M2 may also store processing conditions for processing the substrate W, and the like.

The storage M2 may store a model that indicates a relationship between a processing condition for the peripheral region Wb of the substrate W by the processing liquid and an amount of bending that occurs in the peripheral region Wb of the substrate W when the substrate W is processed under the corresponding processing condition in the state that heating of the peripheral region Wb of the substrate W by the peripheral heating device 61 is not performed. A method of generating the model is as follows, for example. First, a substrate W for a test is held by the rotating/holding device 10. Next, the controller Ctr controls the rotating/holding device 10 to rotate the substrate W for the test while attracting and holding the rear surface thereof. In this state, the controller Ctr controls the heating device 50 to heat the central region Wa of the substrate W. Then, the controller Ctr controls the processing liquid supplies 20 and 30 to supply the processing liquid to the peripheral region Wb of the substrate W. At this time, since the peripheral region Wb of the substrate W supplied with the processing liquids is cooled, a temperature gradient is generated between the central region Wa and the peripheral region Wb of the substrate W, which causes the bending of the peripheral region Wb of the substrate W. The amount of the bending at this time is detected by the detector 70, and is stored as the model in the storage M2, matched with the processing condition. The processing condition may include, by way of non-limiting example, the kinds of the processing liquid, a supply flow rate of the processing liquid, a supply temperature of the processing liquid, a rotation speed of the substrate W, a heating temperature of the substrate W by the heating device 70, etc.

Contrary to the above, however, as the peripheral region Wb of the substrate W is heated by the peripheral heating device 61 when the processing liquid is supplied to the peripheral region Wb of the substrate W, the temperature gradient is reduced, and the peripheral region Wb of the substrate W is less likely to be bent. For this reason, when the amount of bending is obtained, a heating temperature of the peripheral heating device 61 at which the amount of bending approaches 0 can be obtained. Therefore, the model may further store the heating temperature of the peripheral heating device 61 at which the amount of bending approaches 0 in correspondence with the amount of bending.

The processor M3 is configured to process various data. The processor M3 may generate a signal for operating each component of the substrate processing system 1 based on the various data stored in the storage M2, for example.

The instructor M4 is configured to transmit the operation signal generated in the processor M3 to each component of the substrate processing system 1.

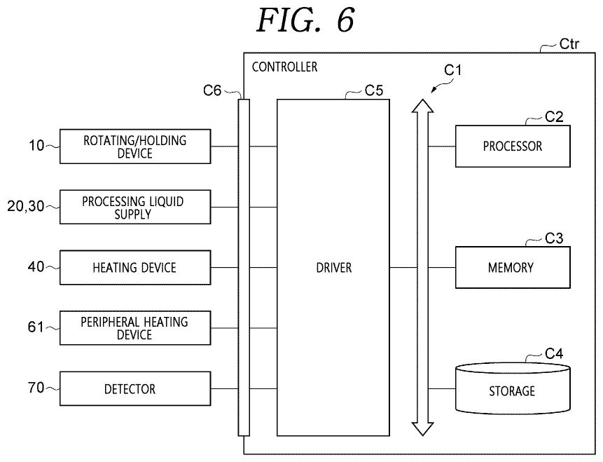

The hardware of the controller Ctr may be composed of, for example, one or more control computers. The controller Ctr may include a circuit C1 as a hardware configuration, as shown in FIG. 6. The circuit C1 may be composed of electrical circuit elements (circuitry). The circuit C1 may include, by way of example, a processor C2, a memory C3, a storage C4, a driver C5, and an input/output port C6.

The processor C2 may be configured to execute a program in cooperation with at least one of the memory C3 and the storage C4 and execute input/output of signals through the input/output port C6, thus implementing each of the above-described functional modules. The memory C3 and the storage C4 may function as the storage M2. The driver C5 may be a circuit configured to drive each component of the substrate processing system 1. The input/output port C6 may be configured to relay input/output of signals between the driver C5 and each component of the substrate processing system 1.

The substrate processing system 1 may be equipped with one controller Ctr, or may be equipped with a controller group (control device) composed of a plurality of controllers Ctr. When the substrate processing system 1 has the controller group, each of the above-described functional modules may be implemented by one controller Ctr, or may be implemented by a combination of two or more controllers Ctr. When the controller Ctr is composed of a plurality of computers (circuits C1), each of the above-described functional modules may be implemented by one computer (circuit C1), or may be implemented by a combination of two or more computers (circuits C1). The controller Ctr may have a plurality of processors C2. In this case, each of the above-described functional modules may be implemented by one processor C2, or may be implemented by a combination of two or more processors C2.

### Substrate Processing Method

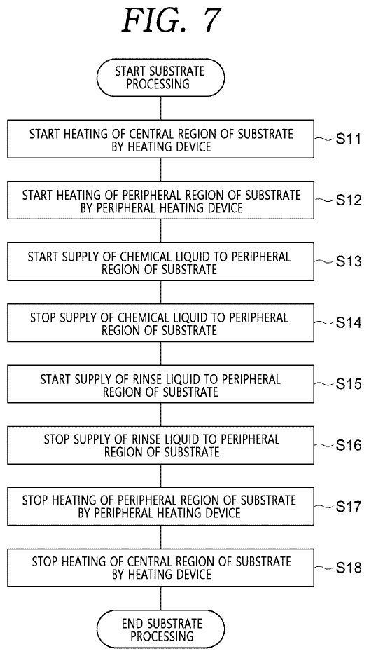

Now, referring to FIG. 7 to FIG. 10, a method of processing the peripheral region Wb of the substrate W by the processing liquid will be described.

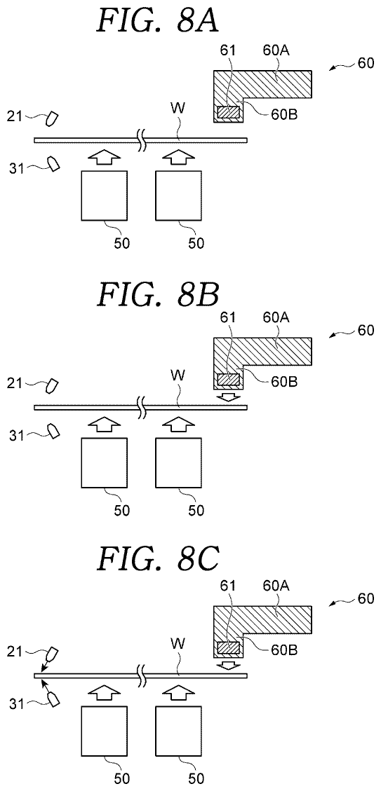

First, the controller Ctr controls the transfer arms A1 and A2 to transfer the substrate W from the carrier 7 to the liquid processing module U. Next, the substrate W is held by the rotating/holding device 10. Then, the controller Ctr controls the rotating/holding device 10 to rotate the substrate W while attracting and holding the rear surface of the substrate W with the holder 13. In this state, the controller Ctr controls the heating device 50 to discharge the heated fluid from the discharge openings 51B and 51C toward the central region Wa of the bottom surface of the substrate W (see a process S11 of FIG. 7 as well as FIG. 8A). As a result, the central region Wa of the substrate W is heated.

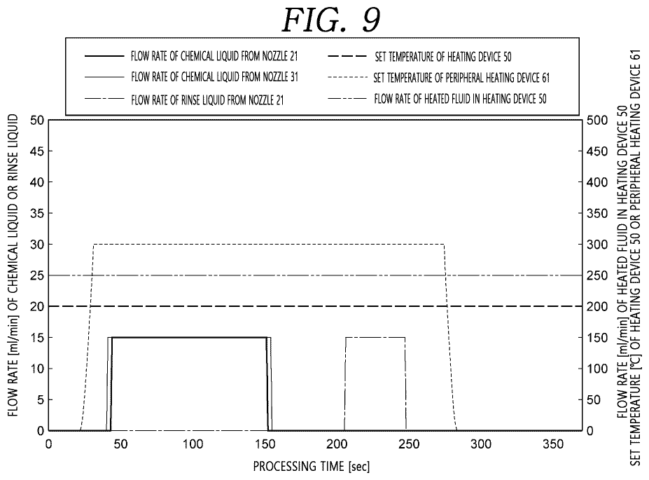

An example of processing conditions in the process S11 is specified below (see FIG. 9).
Rotation speed of the substrate W: about 2400 rpm
Set temperature of the heating device 50: about 200° C.
Flow rate of the heated fluid in the heating device 50: about 250 ml/min

Subsequently, the controller Ctr controls the peripheral heating device 61 to heat the peripheral region Wb of the substrate W (see a process S12 of FIG. 7 as well as FIG. 8B).

An example of processing conditions in the process S12 is specified below (see FIG. 9).
Rotation speed of the substrate W: about 2400 rpm
Set temperature of the heating device 50: about 200° C.
Flow rate of the heated fluid in the heating device 50: about 250 ml/min
Set temperature of the peripheral heating device 61: about 300° C.

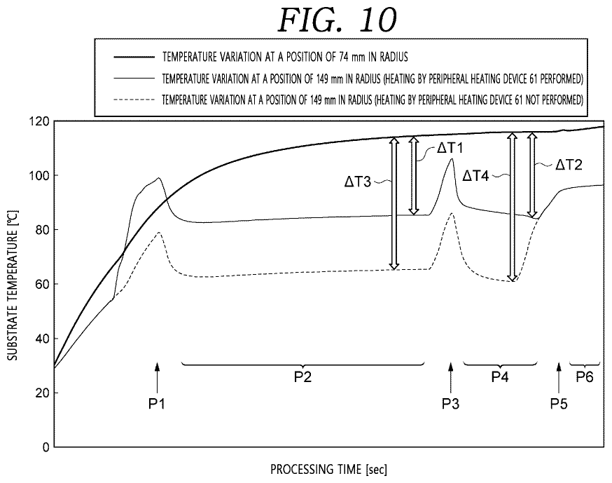

In the process S12, the central region Wa of the substrate W is heated up to about 90° C., and the peripheral region Wb of the substrate W is heated up to about 99° C. (see a time P1 in FIG. 10).

Next, the controller Ctr controls the processing liquid supplies 20 and 30 to supply the chemical liquid to the peripheral region Wb of the substrate W (see a process S13 of FIG. 7 as well as FIG. 8C). As a result, the peripheral region Wb of the substrate W is processed. Further, as illustrated in FIG. 9, the supply of the chemical liquid from the nozzle 21 may be started after the supply of the chemical liquid from the nozzle 31 is begun (for example, after 2 seconds to 5 seconds).

An example of processing conditions in the process S13 is specified below (see FIG. 9).
Rotation speed of the substrate W: about 2400 rpm
Set temperature of the heating device 50: about 200° C.
Flow rate of the heated fluid in the heating device 50: about 250 ml/min
Set temperature of the peripheral heating device 61: about 300° C.
Discharge flow rate of the chemical liquid from the nozzle 21: about 15 ml/min
Discharge flow rate of the chemical liquid from the nozzle 31: about 15 ml/min

In the process S13, the central region Wa of the substrate W is continuously heated by the heating device 50 up to about 90° C. to 115° C. Meanwhile, the temperature of the peripheral region Wb of the substrate W is lowered to about 80° C. as a result of a contact with the chemical liquid (see a period P2 in FIG. 10). Therefore, a temperature difference ΔT1 between the central region Wa and the peripheral region Wb of the substrate W is 36° C. or less. In other words, the controller Ctr sets the heating temperature of the peripheral heating device 61 based on the processing condition of the peripheral region Wb of the substrate W and the model stored in the storage M2 such that the temperature difference ΔT1 becomes 36° C. or less.

Thereafter, upon the lapse of a preset processing time (about 110 seconds in the example of FIG. 9), the controller Ctr controls the processing liquid supplies 20 and 30 to stop the supply of the chemical liquid to the peripheral region Wb of the substrate W (process S14 of FIG. 7). At this time, the heating of the substrate W by the heating device 50 and the peripheral heating device 61 is continued. Therefore, in the process S14, the temperature of the central region Wa of the substrate W reaches about 115° C., and the temperature of the peripheral region Wb of the substrate W reaches about 105° C. (see a time P3 in FIG. 10).

Next, after a preset processing time elapses (after about 50 seconds in the example of FIG. 9), the controller Ctr controls the processing liquid supply 20 to supply a rinse liquid to the peripheral region Wb of the substrate W (see a process S15 in FIG. 7). The rinse liquid washes away the chemical liquid attached to the peripheral region Wb of the substrate W, residues processed by the chemical liquid, and the like from the peripheral region Wb of the substrate W.

An example of processing conditions in the process S15 is shown below (see FIG. 9).
Rotation speed of the substrate W: about 2400 rpm
Set temperature of the heating device 50: about 200° C.
Flow rate of the heated fluid in the heating device 50: about 250 ml/min
Set temperature of the peripheral heating device 61: about 300° C.
Flow rate of the chemical liquid from the nozzle 21: about 15 ml/min

In the process S15, the central region Wa of the substrate W is continuously heated by the heating device 50 up to about 115° C. Meanwhile, the temperature of the peripheral region Wb of the substrate W is lowered to about 82° C. as a result of a contact with the chemical liquid (see a period P4 of FIG. 10). Therefore, a temperature difference ΔT2 between the central region Wa and the peripheral region Wb of the substrate W is 36° C. or less. In other words, the controller Ctr sets the temperature of the peripheral heating device 61 based on the processing condition of the peripheral region Wb of the substrate W and the model stored in the storage M2 such that the temperature difference ΔT2 becomes 36° C. or less.

Then, upon the lapse of a predetermined processing time (after about 50 seconds in the example of FIG. 9), the controller Ctr controls the processing liquid supply 20 to stop the supply of the rinse liquid to the peripheral region Wb of the substrate W (process S16 in FIG. 7). At this time, the heating of the substrate W by the heating device 50 and the peripheral heating device 61 is continued. Therefore, in the process S16, the central region Wa of the substrate W is heated up to about 115° C., and the peripheral region Wb of the substrate W is heated up to about 93° C. (see a time P5 in FIG. 10).

Next, after a preset processing time elapses (after about 30 seconds in the example of FIG. 9), the controller Ctr controls the peripheral heating device 61 to stop the heating the peripheral region Wb of the substrate W by the peripheral heating device 61 (see a process S17 in FIG. 7). At this time, the heating of the substrate W by the heating device 50 is continued. Therefore, in the process S17, the central region Wa of the substrate W is heated up to about 118° C., and the peripheral region Wb of the substrate W is heated up to about 96° C. (see a period P6 in FIG. 10).

Thereafter, upon the lapse of a set processing time, the controller Ctr controls the peripheral heating device 61 to stop the heating of the central region Wa of the substrate W by the heating device 50 (see a process S18 in FIG. 7). Accordingly, the substrate W is dried, and the processing of the peripheral region Wb of the substrate W is completed.

### Effects

According to the above-described exemplary embodiment, since the heating device 50 and the peripheral heating device 61 heat the central region Wa and the peripheral region Wb of the substrate W, respectively, the temperature gradient between the central region Wa and the peripheral region Wb of the substrate W is reduced at least while the processing liquid is being supplied to the peripheral region Wb of the substrate W. For this reason, it is difficult for the peripheral region Wb of the substrate W to be bent, so it is easy for the processing liquid to land on the target position of the peripheral region Wb of the substrate W. Therefore, it becomes possible to process the peripheral region Wb of the substrate W with higher precision. Besides, since the processing liquid is supplied to the peripheral region Wb while the peripheral region Wb of the substrate W is being heated, the processing of the peripheral region Wb of the substrate W is carried out in the state that the reaction of the processing liquid is more accelerated. This makes it possible to process the peripheral region Wb of the substrate W more efficiently.

According to the above-described exemplary embodiment, before the processing liquid (chemical liquid) is supplied to the peripheral region Wb of the substrate W by the processing liquid supplies 20 and 30, the peripheral region Wb of the substrate W is heated by the peripheral heating device 61. In this case, since the peripheral region Wb of the substrate W is already heated at the time when the processing liquid is supplied to the peripheral region Wb, the temperature variation of the peripheral region Wb of the substrate W is small before and after the start of the supply of the processing liquid. For this reason, the temperature gradient between the central region Wa and the peripheral region Wb of the substrate W becomes smaller. Therefore, the peripheral region Wb of the substrate W can be processed with higher precision.

According to the above-described exemplary embodiment, after the supply of the processing liquid (rinse liquid) to the peripheral region Wb of the substrate W by the processing liquid supply 20 is stopped, the heating of the peripheral region Wb of the substrate W by the peripheral heating device 61 is stopped. In this case, since the peripheral region Wb is still heated when the supply of the processing liquid to the peripheral region Wb of the substrate W is stopped, the temperature variation of the peripheral region Wb of the substrate W is small before and after the supply of the processing liquid is stopped. For this reason, the temperature gradient between the central region Wa and the peripheral region Wb of the substrate W becomes smaller. Therefore, the peripheral region Wb of the substrate W can be processed with higher precision.

According to the above-described exemplary embodiment, the temperature difference ΔT1 (ΔT2) between the central region Wa and the peripheral region Wb of the substrate W is within 36° C. In this case, the bending of the peripheral region Wb of the substrate W is greatly suppressed. For this reason, it becomes possible to process the peripheral region Wb of the substrate W with even higher precision. Furthermore, when processing the peripheral region Wb of the substrate W without using the peripheral heating device 61, the temperature difference ΔT3 (ΔT4) between the central region Wa and the peripheral region Wb of the substrate W is of a large value exceeding 36° C., as illustrated in FIG. 10, so that the peripheral region Wb of the substrate W is highly likely to be bent.

According to the above-described exemplary embodiment, the heating device 50 is positioned below the substrate W held by the rotating/holding device 10, and is configured to heat the central region Wa of the substrate W from the bottom surface side of the substrate W. In this case, it is easy to secure a space for placing devices on the top surface side of the substrate W, and also easy to secure a moving path for the substrate W when the substrate W is held on the rotating/holding device 10. Therefore, the liquid processing module U can be made compact.

According to the above-described exemplary embodiment, the heating device 50 is configured to heat the central region Wa of the substrate W by supplying the heated fluid toward the bottom surface of the substrate W. In this case, the heated fluid supplied toward the bottom surface of the substrate W flows from the central side of the substrate W toward the outer peripheral side of the substrate W. Therefore, the heated fluid blows away the processing liquid supplied to the peripheral region Wb of the substrate W toward the outside of the substrate W while heating the substrate W. Thus, the heating of the substrate W and the cleaning of the rear surface of the peripheral region Wb of the substrate W can be accomplished by one and the same heating device.

According to the above-described exemplary embodiment, the peripheral heating device 61 is disposed to face the peripheral region Wb of the substrate W held by the rotating/holding device 10. In this case, since the peripheral heating device 61 is located near the peripheral region Wb of the substrate W, it becomes possible to heat the peripheral region Wb of the substrate W more effectively.

According to the above-described exemplary embodiment, the heating conditions for the peripheral region Wb of the substrate W by the peripheral heating device 61 are set based on the amount of bending obtained from the model and the processing conditions of the peripheral region Wb of the substrate W. In this case, by acquiring the model in advance, the heating conditions that reduce the amount of bending are selected based on the processing conditions of the peripheral region Wb of the substrate W. Therefore, even if the processing conditions vary between substrates to be processed, the output of the peripheral heating device 61 is controlled according to the corresponding processing conditions. Therefore, the peripheral region Wb of the substrate W can be processed with much higher precision.

### MODIFICATION EXAMPLES

Here, it should be noted that the above-described exemplary embodiments are illustrative in all aspects and are not anyway limiting. The above-described exemplary embodiments may be omitted, replaced and modified in various ways without departing from the scope and the spirit of claims.

(1) Substantially at the same time as the processing liquid (chemical liquid) is supplied to the peripheral region Wb of the substrate W by the processing liquid supplies 20 and 30, the heating of the peripheral region Wb of the substrate W by the peripheral heating device 61 may be begun. Alternatively, within a preset time (for example, within about 1 second to about 5 seconds) after the processing liquid (chemical liquid) is supplied to the peripheral region Wb of the substrate W by the processing liquid supplies 20 and 30, the peripheral region Wb of the substrate W may be started to be heated by the peripheral heating device 61.

(2) Substantially at the same time as the supply of the processing liquid (rinse liquid) to the peripheral region Wb of the substrate W by the processing liquid supply 20 is stopped, the heating of the peripheral region Wb of the substrate W by the peripheral heating device 61 may be stopped. Alternatively, before the supply of the processing liquid (rinse liquid) to the peripheral region Wb of the substrate W by the processing liquid supply 20 is stopped (for example, before about 1 second to about 5 seconds), the heating of the peripheral region Wb of the substrate W by the peripheral heating device 61 may be stopped.

(3) In the above-described exemplary embodiment, the output of the peripheral heating device 61 is controlled such that the temperature difference ΔT1 (ΔT2) between the central region Wa and the peripheral region Wb of the substrate W is within 36° C. Depending on the processing conditions of the peripheral region Wb of the substrate W, however, the output of the peripheral heating device 61 may be controlled such that the temperature difference ΔT1 (ΔT2) is in the range of about 0° C. to about 36° C. That is, depending on the size of the substrate W, the kind of the processing liquid (the specific heat of the processing liquid), the discharge flow rate of the processing liquid, the processing time of the peripheral region Wb of the substrate W, the heating time by the heating device 50 or the peripheral heating device 61, and the like, the output of the peripheral heating device 61 may be controlled such that the temperature difference ΔT1 (ΔT2) falls within the set range.

(4) The position of the heating device 50 is not particularly limited as long as it can heat the central region Wa of the substrate W. For example, the heating device 50 may be positioned above the substrate W held by the rotating/holding device 10.

(5) The position of the peripheral heating device 61 is not particularly limited as long as it can heat the peripheral region Wb of the substrate W. By way of example, the peripheral heating device 61 does not have to be provided in the cover 60, and may be positioned next to or below the substrate W held by the rotating/holding device 10.

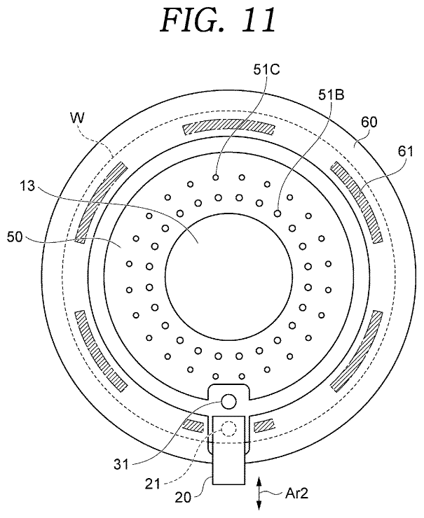

(6) The peripheral heating device 61 may be extended in a substantially circular ring shape so as to overlap approximately the entire circumference of the peripheral region Wb of the substrate W when viewed from above or below, or may be extended in a substantially circular arc shape (a major arc shape or a minor arc shape) so as to overlap a part of the peripheral region Wb of the substrate W. Alternatively, as illustrated in FIG. 11, a plurality of peripheral heating devices 61 may be arranged along the peripheral region Wb of the substrate W when viewed from above or below. Alternatively, the single peripheral heating device 61 may spot-heat one point of the peripheral region Wb of the substrate W.

(7) In the above-described exemplary embodiment, the output of the peripheral heating device 61 is controlled based on the previously acquired model. However, when processing a plurality of substrates W having almost the same processing conditions for the peripheral regions Wb thereof, the output of the peripheral heating device 61 may be fixed. Alternatively, the amount of bending generated as a result of supplying the processing liquid to the peripheral region Wb of the substrate W may be detected by the detector 70, and the heating conditions for heating the peripheral region Wb of the substrate W by the peripheral heating device 61 may be set by the controller Ctr based on the detected amount of bending. In this case, since the heating conditions of the peripheral region Wb of the substrate W vary based on the amount of bending detected by the detector 70, the output of the peripheral heating device 61 is controlled over time such that the amount of bending decreases in real time during the processing of the substrate W. Therefore, the peripheral region Wb of the substrate W can be processed with even higher precision.

### OTHER EXAMPLES

Example 1. A substrate processing apparatus includes a rotating/holding device configured to hold and rotate a substrate; a processing liquid supply configured to supply a processing liquid to a peripheral portion of the substrate; a heating device configured to heat a region including a central portion of the substrate; a peripheral heating device configured to heat the peripheral portion of the substrate; and a controller. The controller is configured to perform: rotating the substrate by controlling the rotating/holding device; supplying the processing liquid to the peripheral portion of the substrate being rotated by controlling the processing liquid supply; and heating, by controlling the heating device and the peripheral heating device, at least while the processing liquid is being supplied to the peripheral portion of the substrate, the region including the central portion of the substrate and the peripheral portion of the substrate, respectively, such that a temperature difference between the region including the central portion of the substrate and the peripheral portion of the substrate falls within a preset range.

However, as disclosed in Patent Document 1, etc., in the conventional substrate processing apparatus, the region including the central portion of the substrate is heated in order to accelerate the reaction of the processing liquid. In this case, since the temperature of the processing liquid is generally lower than that of the heated substrate, the temperature of the peripheral portion of the substrate may decrease when the processing liquid is supplied to the peripheral portion of the substrate to process the peripheral portion, resulting in the temperature gradient between the region including the central portion of the substrate and the peripheral portion of the substrate. The temperature gradient may cause the bending of the peripheral portion of the substrate, and the landing position of the processing liquid on the peripheral portion of the substrate may be deviated from the target position. As a result, there is a concern that the processing precision of the peripheral portion of the substrate may be adversely affected.

According to Example 1, however, since the heating device and the peripheral heating device heat the region including the central portion of the substrate and the peripheral portion of the substrate, respectively, the temperature gradient between the region including the central portion of the substrate and the peripheral portion of the substrate becomes small, at least while the processing liquid is being supplied to the peripheral portion of the substrate. For this reason, it becomes difficult for the peripheral portion of the substrate to be bent, so that the processing liquid is allowed to easily land on the target position of the peripheral portion of the substrate. Therefore, it becomes possible to process the peripheral portion of the substrate with higher precision. In addition, since the processing liquid is supplied to the peripheral portion while the peripheral portion of the substrate is being heated, the processing of the peripheral portion of the substrate proceeds in the state that the reaction of the processing liquid is further accelerated. Therefore, it becomes possible to process the peripheral portion of the substrate more efficiently.

Example 2. In the apparatus of Example 1, the heating of the region including the central portion of the substrate and the peripheral portion of the substrate may include heating the peripheral portion of the substrate by the peripheral heating device before the processing liquid is supplied to the peripheral portion of the substrate by the processing liquid supply. In this case, since the peripheral portion is already heated at the time when the processing liquid is supplied to the peripheral portion of the substrate, the temperature variation of the peripheral portion of the substrate is reduced before and after the start of the supply of the processing liquid. Therefore, the temperature gradient between the region including the central portion of the substrate and the peripheral portion of the substrate is reduced. Therefore, it becomes possible to process the peripheral portion of the substrate with higher precision.

Example 3. In the apparatus of Example 1 or Example 2, the heating of the region including the central portion of the substrate and the peripheral portion of the substrate may include stopping heating of the peripheral portion of the substrate by the peripheral heating device after a supply of the processing liquid to the peripheral portion of the substrate by the processing liquid supply is stopped. In this case, since the peripheral portion is heated even at the time when the supply of the processing liquid to the peripheral portion of the substrate is stopped, the temperature variation of the peripheral portion of the substrate is reduced before and after the supply of the processing liquid is stopped. Therefore, the temperature gradient between the region including the central portion of the substrate and the peripheral portion of the substrate is reduced. Therefore, it becomes possible to process the peripheral portion of the substrate with higher precision.

Example 4. In the apparatus of any one of Examples 1 to 3, the temperature difference between the region including the central portion of the substrate and the peripheral portion of the substrate may be within 36° C. In this case, the bending of the peripheral portion of the substrate is greatly suppressed. Therefore, it becomes possible to process the peripheral portion of the substrate with even higher precision.

Example 5. In the apparatus of any one of Examples 1 to 4, the heating device may be positioned below the substrate held by the rotating/holding device, and configured to heat the region including the central portion of the substrate from a bottom surface side of the substrate. In this case, it is easy to secure the space for placing the devices on the top surface side of the substrate, and it is also easy to secure the moving path for the substrate when the substrate is held by the rotating/holding device. Therefore, the substrate processing apparatus can be made compact.

Example 6. In the apparatus of Example 5, the heating device may be configured to heat the region including the central portion of the substrate by supplying a heated fluid toward a bottom surface of the substrate. In this case, the heated fluid supplied toward a bottom surface of the substrate flows from the central side of the substrate toward the outer peripheral side of the substrate. Therefore, the heated fluid blows away the processing liquid supplied to the peripheral portion of the substrate toward the outside of the substrate while heating the substrate. Thus, the heating of the substrate and the cleaning of the rear surface side of the peripheral portion of the substrate can be accomplished by one and the same heating device.

Example 7. In the apparatus of any one of Examples 1 to 6, the peripheral heating device may be disposed to face the peripheral portion of the substrate held by the rotating/holding device. In this case, since the peripheral heating device is located near the peripheral portion of the substrate, it becomes possible to heat the peripheral portion of the substrate more effectively.

Example 8. In the apparatus of any one of Examples 1 to 7, the controller may be configured to store a model representing a relationship between a processing condition for the peripheral portion of the substrate with the processing liquid and an amount of bending that occurs in the peripheral portion of the substrate when the substrate is processed under the processing condition in a state that the peripheral portion of the substrate is not heated by the peripheral heating device, and the heating of the region including the central portion of the substrate and the peripheral portion of the substrate may include setting a heating condition for the peripheral portion of the substrate by the peripheral heating device, based on the model and the amount of bending obtained from the processing condition for the peripheral portion of the substrate in the supplying of the processing liquid. In this case, by acquiring the model in advance, the heating condition that reduces the amount of bending is selected based on the processing conditions of the peripheral portion of the substrate. Therefore, even if the processing conditions vary between substrates to be processed, the output of the peripheral heating device is controlled according to the corresponding processing conditions. Therefore, it becomes possible to process the peripheral portion of the substrate with even higher precision.

Example 9. The apparatus of any one of Examples 1 to 7 may further include a detector configured to detect an amount of bending of the peripheral portion of the substrate. The heating of the region including the central portion of the substrate and the peripheral portion of the substrate may include setting a heating condition for the peripheral portion of the substrate by the peripheral heating device, based on the amount of bending detected by the detector in the supplying of the processing liquid. In this case, since the heating condition of the peripheral portion of the substrate changes based on the amount of bending detected by the detector, the output of the peripheral heating device is controlled over time such that the amount of bending is reduced in real time during the processing of the substrate. Therefore, it becomes possible to process the peripheral portion of the substrate with much higher precision.

Example 10. A substrate processing method includes supplying a processing liquid to a peripheral portion of a substrate held and being rotated by a rotating/holding device; and heating, at least while the processing liquid is being supplied to the peripheral portion of the substrate, a region including a central portion of the substrate and the peripheral portion of the substrate by a heating device and a peripheral heating device, respectively, such that a temperature difference between the region including the central portion of the substrate and the peripheral portion of the substrate falls within a preset range. In this case, the same effects as in the apparatus of Example 1 are obtained.

Example 11. In the method of Example 10, the heating of the region including the central portion of the substrate and the peripheral portion of the substrate may include heating the peripheral portion of the substrate by the peripheral heating device before the processing liquid is supplied to the peripheral portion of the substrate. In this case, the same effects as in the apparatus of Example 2 are obtained.

Example 12. In the method of Example 10 or Example 11, the heating of the region including the central portion of the substrate and the peripheral portion of the substrate may include stopping heating of the peripheral portion of the substrate by the peripheral heating device after the supplying of the processing liquid to the peripheral portion of the substrate is stopped. In this case, the same effects as in the apparatus of Example 3 are obtained.

Example 13. In the method of any one of Examples 10 to 12, the temperature difference between the region including the central portion of the substrate and the peripheral portion of the substrate may be within 36° C. In this case, the same effects as in the apparatus of Example 4 are obtained.

Example 14. In the method of any one of Examples 10 to 13, the heating device may be positioned below the substrate held by the rotating/holding device, and configured to heat the region including the central portion of the substrate from a bottom surface side of the substrate. In this case, the same effects as in the apparatus of Example 5 are obtained.

Example 15. In the method of Example 14, the heating device may be configured to heat the region including the central portion of the substrate by supplying a heated fluid toward a bottom surface of the substrate. In this case, the same effects as in the apparatus of Example 6 are obtained.

Example 16. In the method of any one of Examples 10 to 15, the peripheral heating device may be disposed to face the peripheral portion of the substrate held by the rotating/holding device. In this case, the same effects as in the apparatus of Example 7 are obtained.

Example 17. The method of any one of Examples 10 to 16 may further include creating a model representing a relationship between a processing condition for the peripheral portion of the substrate with the processing liquid and an amount of bending that occurs in the peripheral portion of the substrate when the substrate is processed under the processing condition in a state that the peripheral portion of the substrate is not heated by the peripheral heating device. The heating of the region including the central portion of the substrate and the peripheral portion of the substrate may include setting a heating condition for the peripheral portion of the substrate by the peripheral heating device, based on the model and the amount of bending obtained from the processing condition for the peripheral portion of the substrate in the supplying of the processing liquid. In this case, the same effects as in the apparatus of Example 8 are obtained.

Example 18. In the method of any one of Examples 10 to 16, the supplying of the processing liquid may include detecting an amount of bending of the peripheral portion of the substrate by a detector during a supply of the processing liquid to the peripheral portion of the substrate, and the heating of the region including the central portion of the substrate and the peripheral portion of the substrate may include setting a heating condition for the peripheral portion of the substrate by the peripheral heating device, based on the amount of bending detected by the detector in the supplying of the processing liquid. In this case, the same effects as in the apparatus of Example 9 are obtained.

Example 19. A computer-readable recording medium having stored thereon computer-executable instructions that, in response to execution, cause a substrate processing apparatus to perform a substrate processing method as described in any one of Examples 10 to 18. In this case, the same effects as in the apparatus of Example 1 are obtained. In the present specification, the computer-readable recording medium may include a non-transitory computer recording medium (for example, various main or auxiliary storage devices) or a transitory computer recording medium (for example, a data signal that can be provided through a network).

### EXPLANATION OF CODES

1: Substrate processing system (substrate processing apparatus)
10: Rotating/holding device
120, 30: Processing liquid supply
50: Heating device
60: Cover
61: Peripheral heating device
70: Detector
Ctr: Controller (control device)
U: Liquid processing module (substrate processing apparatus)
W: Substrate
Wa: Central region
Wb: Peripheral region

1. A substrate processing apparatus, comprising:
a rotating/holding device configured to hold and rotate a substrate;
a processing liquid supply configured to supply a processing liquid to a peripheral portion of the substrate;
a heating device configured to heat a region including a central portion of the substrate;
a peripheral heating device configured to heat the peripheral portion of the substrate; and
a controller having a processor and a memory with a computer readable program stored therein that upon execution of the computer readable program by the processor configures the controller to:
control the rotating/holding device to rotate the substrate;
control the processing liquid supply to supply the processing liquid to the peripheral portion of the substrate being rotated; and
control the heating device and the peripheral heating device to heat, at least while the processing liquid is being supplied to the peripheral portion of the substrate, the region including the central portion of the substrate and the peripheral portion of the substrate, respectively, such that a temperature difference between the region including the central portion of the substrate and the peripheral portion of the substrate falls within a preset range.

2. The substrate processing apparatus of claim 1,
wherein the heating of the region including the central portion of the substrate and the peripheral portion of the substrate comprises heating the peripheral portion of the substrate by the peripheral heating device before the processing liquid is supplied to the peripheral portion of the substrate by the processing liquid supply.

3. The substrate processing apparatus of claim 1,
wherein the heating of the region including the central portion of the substrate and the peripheral portion of the substrate comprises stopping heating of the peripheral portion of the substrate by the peripheral heating device after a supply of the processing liquid to the peripheral portion of the substrate by the processing liquid supply is stopped.

4. The substrate processing apparatus of claim 1,
wherein the temperature difference between the region including the central portion of the substrate and the peripheral portion of the substrate is within 36° C.

5. The substrate processing apparatus of claim 1,
wherein the heating device is positioned below the substrate held by the rotating/holding device, and
the heating device is configured to heat the region including the central portion of the substrate from a bottom surface side of the substrate.

6. The substrate processing apparatus of claim 5,
wherein the heating device is configured to heat the region including the central portion of the substrate by supplying a heated fluid toward a bottom surface of the substrate.

7. The substrate processing apparatus of claim 1,
wherein the peripheral heating device is disposed to face the peripheral portion of the substrate held by the rotating/holding device.

8. The substrate processing apparatus of claim 1,
wherein the controller is further configured to store a model representing a relationship between a processing condition for the peripheral portion of the substrate with the processing liquid and an amount of bending that occurs in the peripheral portion of the substrate when the substrate is processed under the processing condition in a state that the peripheral portion of the substrate is not heated by the peripheral heating device, and the heating of the region including the central portion of the substrate and the peripheral portion of the substrate comprises setting a heating condition for the peripheral portion of the substrate by the peripheral heating device, based on the model and the amount of bending obtained from the processing condition for the peripheral portion of the substrate in the supplying of the processing liquid.

9. The substrate processing apparatus of claim 1, further comprising:
a detector configured to detect an amount of bending of the peripheral portion of the substrate,
wherein the heating of the region including the central portion of the substrate and the peripheral portion of the substrate comprises setting a heating condition for the peripheral portion of the substrate by the peripheral heating device, based on the amount of bending detected by the detector in the supplying of the processing liquid.

10. A substrate processing method, comprising:
supplying a processing liquid to a peripheral portion of a substrate held and being rotated by a rotating/holding device; and
heating, at least while the processing liquid is being supplied to the peripheral portion of the substrate, a region including a central portion of the substrate and the peripheral portion of the substrate by a heating device and a peripheral heating device, respectively, such that a temperature difference between the region including the central portion of the substrate and the peripheral portion of the substrate falls within a preset range.

11. The substrate processing method of claim 10,
wherein the heating of the region including the central portion of the substrate and the peripheral portion of the substrate comprises heating the peripheral portion of the substrate by the peripheral heating device before the processing liquid is supplied to the peripheral portion of the substrate.

12. The substrate processing method of claim 10,
wherein the heating of the region including the central portion of the substrate and the peripheral portion of the substrate comprises stopping heating of the peripheral portion of the substrate by the peripheral heating device after the supplying of the processing liquid to the peripheral portion of the substrate is stopped.

13. The substrate processing method of claim 10,
wherein the temperature difference between the region including the central portion of the substrate and the peripheral portion of the substrate is within 36° C.

14. The substrate processing method of claim 10,
wherein the heating device is positioned below the substrate held by the rotating/holding device, and
the method further comprising heating, by the heating device, the region including the central portion of the substrate from a bottom surface side of the substrate.

15. The substrate processing method of claim 14,
further comprising heating, by the heating device, the region including the central portion of the substrate by supplying a heated fluid toward a bottom surface of the substrate.

16. The substrate processing method of claim 10,
wherein the peripheral heating device is disposed to face the peripheral portion of the substrate held by the rotating/holding device.

17. The substrate processing method of claim 10, further comprising:
creating a model representing a relationship between a processing condition for the peripheral portion of the substrate with the processing liquid and an amount of bending that occurs in the peripheral portion of the substrate when the substrate is processed under the processing condition in a state that the peripheral portion of the substrate is not heated by the peripheral heating device,
wherein the heating of the region including the central portion of the substrate and the peripheral portion of the substrate comprises setting a heating condition for the peripheral portion of the substrate by the peripheral heating device, based on the model and the amount of bending obtained from the processing condition for the peripheral portion of the substrate in the supplying of the processing liquid.

18. The substrate processing method of claim 10,
wherein the supplying of the processing liquid comprises detecting an amount of bending of the peripheral portion of the substrate by a detector during a supply of the processing liquid to the peripheral portion of the substrate, and
the heating of the region including the central portion of the substrate and the peripheral portion of the substrate comprises setting a heating condition for the peripheral portion of the substrate by the peripheral heating device, based on the amount of bending detected by the detector in the supplying of the processing liquid.

19. A non-transitory computer readable medium comprising computer executable program code configured to instruct at least one computer to perform the method according to cause a substrate processing apparatus to perform a substrate processing method as claimed in claim 10.

20. The non-transitory computer readable medium of claim 19,
wherein the heating of the region including the central portion of the substrate and the peripheral portion of the substrate comprises heating the peripheral portion of the substrate by the peripheral heating device before the processing liquid is supplied to the peripheral portion of the substrate.
